(19) United States
(12) Patent Application Publication
(10) Pub. No.: US 2018/0105921 A1
(43) Pub. Date: Apr. 19, 2018

(54) WIRE GRID ENHANCEMENT FILM FOR DISPLAYING BACKLIT AND THE MANUFACTURING METHOD THEREOF

(71) Applicant: Wuhan China Star Optoelectronics Technology, Co., Ltd., Wuhan, Hubei (CN)

(72) Inventors: Hongqing CUI, Shenzhen, Guangdong (CN); Guowei ZHA, Shenzhen, Guangdong (US)

(73) Assignee: Wuhan China Star Optoelectronics Technology Co., Ltd., Wuhan, Hubei (CN)

(21) Appl. No.: 15/111,737

(22) PCT Filed: Jun. 15, 2016
(86) PCT No.: PCT/CN2016/082307

§ 371 Date: Jul. 14, 2016

(30) Foreign Application Priority Data
Apr. 5, 2016 (CN) 2016102069848

(51) Int. Cl. C23C 14/04; C23C 14/20

(52) U.S. Cl. CPC C23C 14/042; G02F 1/1368; C23C 14/20

(57) ABSTRACT

The present disclosure relates to a wire grid enhancement film for displaying backlit and the manufacturing method thereof. The method includes coating a photo-resist layer on a surface of a substrate, adopting a nano-imprinting process to form a nano-scale photo-resist grid on a photo-resist layer, and applying a curing process, and forming a metal film on the cured photo-resist grid. The photo-resist grid is manufactured by roll-to-roll nano-imprinting process. The metal films having cross sections of different shapes may be formed on the cured photo-resist grid. The manufacturing process is simple and the cost may be saved.

### BACKGROUND OF THE INVENTION

### 1. Field of the Invention

The present disclosure relates to display technology, and more particularly to a wire grid enhancement film for displaying backlit and the manufacturing method thereof.

### 2. Discussion of the Related Art

Polarizer is one core technology of TFT LCDs. The optical transmittance rate of the conventional absorption polarizers is only around 42% due to the selectively transmittance and scattering with respect to polarized states. Conventionally, a brightness enhance film, such as a dual-brightness enhance film (DBEF) and a wire grid is configured between the backlit and the cell, wherein DBEF is a reflective polarizer. The DBEF selectively reflect the light beams from the backlight system such that the reflected light beams are not absorbed by the down polarizer, and thus the polarized light beams may be repeatedly utilized. However, as the extinction ratio of the conventional DBEF is not high, the absorption polarizer is still necessary. Generally, the wire grid is manufactured by adopting microelectronic lithography and etching, and the extinction ratio is high. By combining the reflective polarizer and the reflective sheet, a high enhancement coefficient for wire grid may be obtained. However, the uniformity of the etching process may be a great challenge for mass productions, especially for the creation of complicated structural wire gird, with cross-sections of prism and trapezium.

### SUMMARY

The present disclosure relates to a wire grid enhancement film for displaying backlit and the manufacturing method thereof, which may address the above mentioned issues such as the complicated manufacturing process and the unsatisfactory enhancement coefficients for traditionally enhancement films.

In one aspect, a manufacturing method of enhancement films of wire grids for displaying backlit includes: coating a photo-resist layer on a surface of a substrate, wherein the substrate is a flexible substrate; adopting a nano-imprinting process to form a nano-scale photo-resist grid on the photo-resist layer, and applying a curing process, and cross sections of the photo-resist grid are a plurality of rectangles or trapeziums spaced apart from each other; and forming a metal film on the cured photo-resist grid, and the metal film is formed on top surfaces of the rectangles and the same lateral surface by an inclined deposition method.

In another aspect, a manufacturing method of enhancement films of wire grids for displaying backlit includes: coating a photo-resist layer on a surface of a substrate; adopting a nano-imprinting process to form a nano-scale photo-resist grid on a photo-resist layer, and applying a curing process; and forming a metal film on the cured photo-resist grid.

Wherein cross sections of the photo-resist grid include a plurality of rectangles spaced apart from each other, and the metal film is formed on top surfaces of the rectangles and the same lateral surface by an inclined deposition method.

Wherein cross sections of the photo-resist grid include a plurality of trapeziums spaced apart from each other, and the metal film is formed on top surfaces of the rectangles and the same lateral surface by an inclined deposition method.

Wherein cross sections of the photo-resist grid include a plurality of triangles spaced apart from each other, and the metal film is formed on top surfaces of the triangles and the same lateral surface by an inclined deposition method.

Wherein cross sections of the photo-resist grid include a plurality of rectangles spaced apart from each other, and the metal film is formed on top surfaces of the rectangles and gap areas between the rectangles, and the metal films on the top surfaces of the rectangles and the metal films in the gap areas are not connected.

Wherein a grid period is in a range from 40 to 100 nm, a grid width is in a range from 10 to 50 nm, and a grid thickness is in a range from 40 to 200 nm.

Wherein a grid period is in a range from 100 to 300 nm, a grid width is in a range from 100 to 200 nm, and a grid thickness is in a range from 100 to 200 nm.

Wherein a grid period is in a range from 100 to 200 nm, a grid width is in a range from 60 to 70 nm, and a grid thickness is in a range from 30 to 50 nm.

Wherein the substrate is a flexible substrate, and the metal film is made of Al or Ag.

Wherein the curing process is optical radiation or heat setting, and the metal film is formed by evaporation or sputtering.

In another aspect, a wire grid enhancement film for displaying backlit is manufactured by the above manufacturing method.

In view of the above, the photo-resist grid is manufactured by roll-to-roll nano-imprinting process. The metal films having cross sections of different shapes, which may be formed on the cured photo-resist grid. The manufacturing process is simple and the cost may be saved. At the same time, the substrate of the nano-imprinting process may be applicable to the wire grid enhancement film, has a plurality of complicated patterns. In addition, the optical gain of the TFT-LCD may be enhanced. The P-type transmittance rate is enhanced, and the S-type reflective rate may be maintained.

### BRIEF DESCRIPTION OF THE DRAWINGS

FIG. 1 is a schematic view showing the backlit enhancement structure.

FIG. 2 is a flowchart illustrating the manufacturing method of the wire grid enhancement film for displaying backlit in accordance with one embodiment.

FIG. 3 is a schematic view showing the shapes of three grid patterns and the impression molds.

FIG. 4 is a schematic view of the metallic film formed by the photo-resist patterns of FIG. 3.

FIG. 5 is a curve diagram showing the relationship between the Tp and Rs and the wavelength simulated by FDTD.

FIG. 6 is a schematic view showing four photo-resist patterns and the metallic film structures.

FIG. 7 is a schematic view showing the impression process of the photo-resist grid.

FIG. 8 is curve diagram showing the polarized optical characteristics of the dual-layers wire grid.

FIG. 9 is curve diagram showing the polarized optical characteristics of one enhanced dual-layers wire grid.

FIG. 10 is a curve diagram sowing the polarized optical characteristics of the dual-layers wire grid of FIG. 9 after the duty cycle ratio is enhanced.

FIG. 11 is a curve diagram sowing the polarized optical characteristics of the dual-layers wire grid of FIG. 9 after the photo-resist thickness (h2) is enhanced.

### DETAILED DESCRIPTION OF THE EMBODIMENTS

Embodiments of the invention will now be described more fully hereinafter with reference to the accompanying drawings, in which embodiments of the invention are shown.

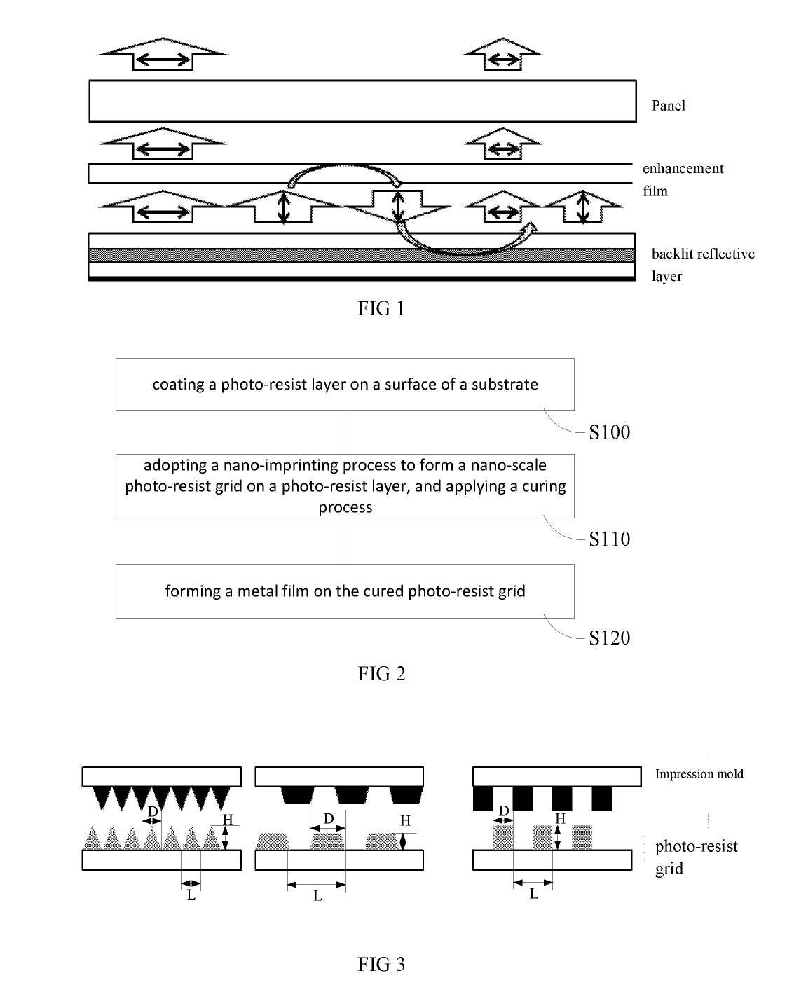

FIG. 1 is a schematic view showing the backlit enhancement structure, wherein the enhancement film is combined with the reflective sheet to obtain greater enhancement coefficient.

FIG. 2 is a flowchart illustrating the manufacturing method of the wire grid enhancement film for displaying backlit in accordance with one embodiment. The method includes the following steps.

In step S100, coating a photo-resist layer on a surface of the substrate.

In step S100, a flexible substrate is adopted as a base of the wire grid, wherein the flexible substrate is made of flexible materials, such as polymers or PET, so as to cooperate with conventional roll-to-roll devices. At the same time, the flexible substrate is characterized by good transmittance so as to be applicable for TFT-LCD. In addition, the sticky of the photo-resist is low, and thus the photo-resist may be separated from the impression mold of the roll-to-roll devices. Also, after being cured, the mechanical performance of the flexible substrate is good, which may be a good support.

In step S110, adopting a nano-imprinting process to form a nano-scale photo-resist grid on a photo-resist layer, and applying a curing process.

In step S110, the roll-to-roll nano-imprinting process is adopted to form patterns on a surface of the photo-resist. Such configuration contributes to mass production, and may be repeatedly conducted. The curing process may be optical radiation or heat setting.

The photo-resist grid structure relates to a periodical sequence including air gaps and the photo-resist, wherein the cross sections of the photo-resist may be, but not limited to, rectangular, trapezium-shaped, or triangular. The cross sections of the photo-resist are closely related with the shapes of imprint mold. The shapes of the imprint mold and the corresponding grid are shown in FIG. 3, wherein three shapes are shown for instance. The grid period is defined as the sum width of the grid width and the gap between adjacent metal grid , which is indicated as “L” in FIG. 3. The grid period and the grid width have different optimal ranges for different grid structure. In one example, the grid period of the triangular photo-resist or trapezium photo-resist is about 100-300 nm. The grid width (as indicated by “D”) is about 100-200 nm, and the grid thickness (as indicated by “H”) is about 100-200 nm. With respect to the rectangular photo-resist, the grid period is about 40-100 nm, the grid width is about 10-50 nm, and the grid thickness is about 40-200 nm. Taking the backlit collecting efficiency into a comprehensive consideration, the structure parameters of wire grid should be specially designed with expected transmission and reflection rate.

In step S120, forming a metal film on the cured photo-resist grid on the photo-resist.

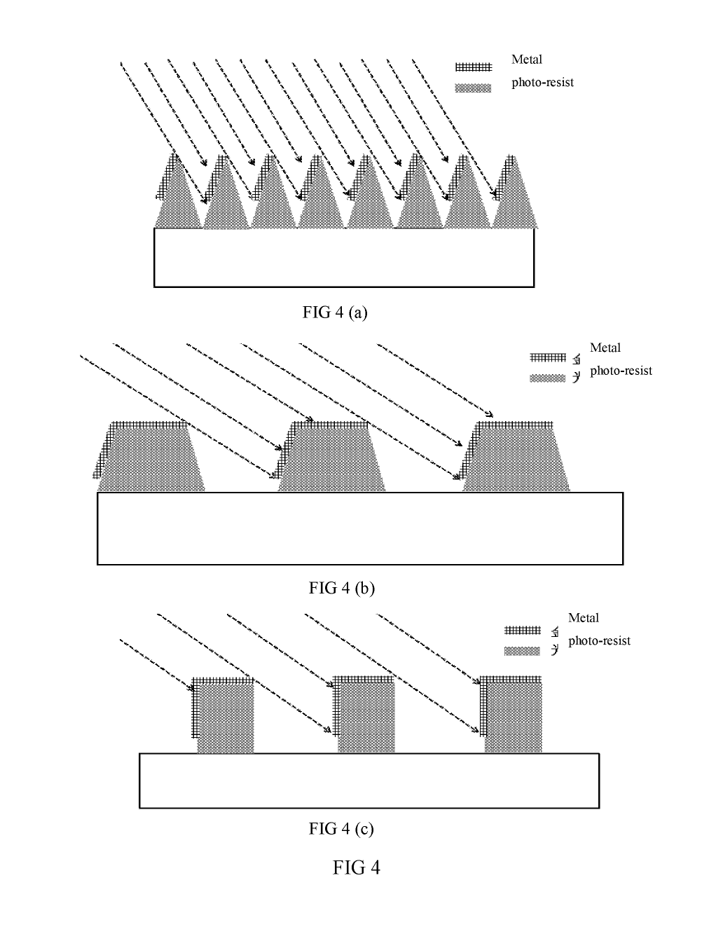

In step S120, the metal film is formed by directional inclined evaporation or sputtering. That is, the plane of the substrate of the grid is not perpendicular to the metal deposition direction. In addition, the metal deposition direction is characterized by good collimation with little distribution of particle beam along the non-parallel directions. As shown in FIG. 4, the directions of the inclined evaporation is indicated by arrows. As the adjacent periodic photo-resist grid may block steaming metal beams such that only parts of the photo-resist grid, exposed in the beam direction are deposited with the metal films. In addition, areas deposited with the metal is highly relevant to the inclined angle (θ) of the evaporation and the height of the photo-resist grid. With respect to the photo-resist grids of different shapes shown in FIG. 3, the shapes of the wire grids are shown in FIG. 4(a)-(c).

In FIG. 4(a), the cross sections of the photo-resist grids are a plurality of triangles spaced apart from each other, and the metal films are formed on the same side with the triangles by the inclined deposition method.

In FIG. 4(b), the cross sections of the photo-resist grids are a plurality of trapeziums paced apart from each other, and the metal films are formed on the top surfaces of the trapeziums and on the same sides of the trapeziums by the inclined deposition method.

In FIG. 4(c), the cross sections of the photo-resist grids are a plurality of rectangles spaced apart from each other, and the metal films are formed on the top surfaces of the rectangles and on the same sides of the rectangles by the inclined deposition method.

Preferably, the thickness of the metal film is in a range from 10 to 100 nm. The metal film is made of material with a large imaginary refractive index such that the wire grid is characterized with great polarization extinction ratio. Preferably, the metal film is made of Al or Ag.

The backlit enhancement system is composed of the wire grid and the reflective layer as shown in FIG. 1. The location of the grid surface with respect to the backlit is not limited thereto. That is, regardless of the grid surface facing toward or facing away the backlit source, the reflective polarized characteristics is comparatively consistent. The reflective layer of FIG. 1 may be a diffuse reflector or may be the metal mirror reflection and a quarter glass (please refer to “ Low Fill—Factor Wire Grid Polarizers for LCD Backlighting”). In one example, the overall backlit light-emitting efficiency (the metal mirror reflection and the quarter glass) may be calculated by the equation: T=0.5Tp*(1+RRs), wherein Tp, R, and Rs respectively relates to the transmittance rate of the P-type light beams, the reflective rate of the mirror, and the reflective rate of the S-type light beams, wherein R approximately equals to one. When the light beams pass through a surface of the optical component, such as a beam splitter, the reflective and transmittance characteristics depend on the polarized state. Under the circumstance, the coordinate system is defined by the plane containing the incident and the reflective light beams. The P-polarization relates to the scenario where the polarization vector of the light beams is within the plane, and the S-polarization relates to the scenario where the polarization vector of the light beams is perpendicular to the plane. The input polarized state may be the vector sum of the S and P components.

In the first embodiment, the photo-resist grid structure having the triangular cross-section is manufactured by the roll-to-roll nano-imprinting process. Afterwards, the directional inclined evaporation is adopted to deposit the metal on one lateral side of the prism. As shown in FIG. 4(a), the photo-resist grid period may be in a range from 100 to 300 nm, the grid width is in a range from 100 to 200 nm, the grid thickness is in a range from 100 to 200 nm, and the thickness of the metal film is in a range from 10 to 100 nm. FIG. 5(a) is a curve diagram showing the relationship between the Tp and Rs and the wavelength simulated by FDTD, the cross section of the photo-resist grid is triangular. Wherein Rs is greater than 0.9, Tp is about 0.7, and the minimum value is calculated by: T=0.5*0.7*(1+0.9)=66.5%. Compared to the conventional absorption polarizer having the transmittance rate about 42%, the enhancement factor is about 58%.

In the second embodiment, the photo-resist grid structure having the trapezium cross-section is manufactured by the roll-to-roll nano-imprinting process. Afterwards, the directional inclined evaporation is adopted to deposit the metal on the top surface and one lateral side of the trapezium. As shown in FIG. 4(b), the photo-resist grid period may be in a range from 100 to 300 nm, the grid width is in a range from 100 to 200 nm, the grid thickness is in a range from 100 to 200 nm, and the thickness of the metal film is in a range from 10 to 100 nm. FIG. 5(b) is a curve diagram showing the relationship between the Tp and Rs and the wavelength simulated by FDTD, the cross section of the photo-resist grid is trapezium. Wherein Rs is greater than 0.8, Tp is about 0.6, and the minimum value is calculated by: T=0.5*0.6*(1+0.8)=54%. Compared to the conventional absorption polarizer, the enhancement ratio is about 29%.

In the third embodiment, the photo-resist grid structure having the rectangular cross-section is manufactured by the roll-to-roll nano-imprinting process. Afterward, the directional inclined evaporation is adopted to deposit the metal on the top surface and one lateral side of the rectangular. As shown in FIG. 4(c), the photo-resist grid period may be in a range from 40 to 100 nm, the grid width is in a range from 10 to 50 nm, the grid thickness is in a range from 40 to 200 nm, and the thickness of the metal film is in a range from 10 to 100 nm. In view of the FDTD simulation, it can be understood that the Tp may be smaller than 0.5 when the grid width is too large, i.e., greater than or equal to 60 nm, which results in that the overall transmittance rate is much better than the conventional absorption polarizer. FIG. 5(c) is a curve diagram showing the relationship between the Tp and Rs and the wavelength simulated by FDTD, the cross section of the photo-resist grid is rectangular. Wherein Rs is greater than 0.8, Tp is about 0.65, and the minimum value is calculated by: T=0.5*0.65*(1+0.8)=58.5%. Compared to the conventional absorption polarizer, the enhancement is about 40%.

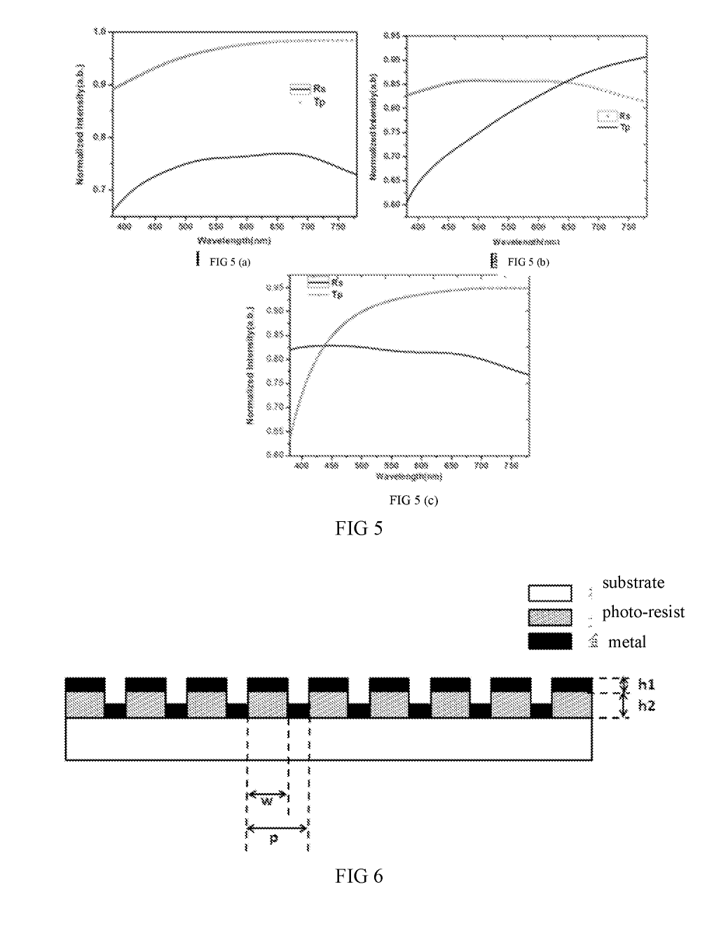

In the fourth embodiment, in order to enhance the transmittance rate of the P-type light beams and maintain the reflective rate of the S-type light beams, the grid enhancement film as shown in FIG. 6 is also provided. The cross section of the photo-resist grid includes a plurality of rectangles spaced apart from each other. The metal film is formed on the top surfaces of the rectangles and on gap areas between the rectangles. The metal films on the top surfaces of the rectangles and the metal films in the gap areas are not connected with the metal films on the substrates so as to prevent the transmittance rate of the P-type from being affected.

The enhancement grid structure is also referred to as the dual-layers metal grid. The optical performance of the dual-layers metal grid may be analyzed by FDTD algorithms, wherein the structure of the dual-layers metal grid is shown in FIG. 6. The grid period is defined as “p”, the grid width is defined as “w”, and the thickness of the photo-resist and the metal film are respectively defined as “h2” and “h1.” The transmittance rate of the P-type is defined as “Tp”, the reflective rate of the S-type is defined as “Rs”, the backlit reflective layer includes a full-reflective layer and the quarter glass, the reflective rate is defined as “R” with the value close to 1. The overall transmittance rate of the backlit system is: T=0.5Tp*(1+RRs)=0.5Tp*(1+Rs).

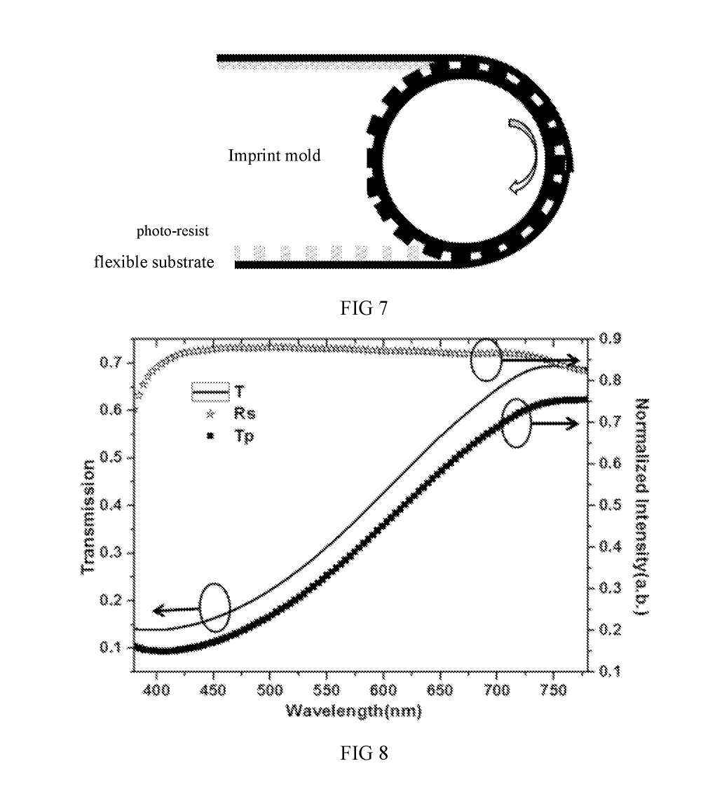

The dual-layers wire grid includes the flexible substrate (the base), the photo-resist grid, and the metal film on the top and the bottom surfaces of the photo-resist grid. FIG. 7 is a schematic view showing the imprint process of the photo-resist grid.

The grid period of the dual-layers wire grid is in a range from 100 to 200 nm, the duty cycle ratio (the ratio of the dimension of the photo-resist to the dimension of the substrate) is in a range from 0.5 to 0.6, the thickness of the photo-resist grid is in a range from 60 to 70 nm, the thickness of the metal film is in a range from 30 to 50 nm, the S-type reflective rate of the dual-layers wire grid is about 85%, the P-type transmittance rate is about 60%, and the optical transmittance rate of the enhancement film of the dual-layers wire grid is greater than 55.5%. The optical transmission is increased by a factor of 32% when compared to the conventional absorption polarizer.

FIG. 8 is curve diagram showing the polarized optical characteristics of the dual-layers wire grid. The parameters are P=200 nm, w=100 nm, h1=50 nm, and h2=140 nm. The dotted lines respectively relates to P-type transmittance rate and the S-type reflective rate. The solid line relates to the overall transmittance rate of the enhancement film, wherein S-type reflective rate is increased along the wavelength within the visible spectrum. The minimum value may be 0.1 such that the overall transmittance rate is lower than that of the absorption polarizer within a short wavelength band.

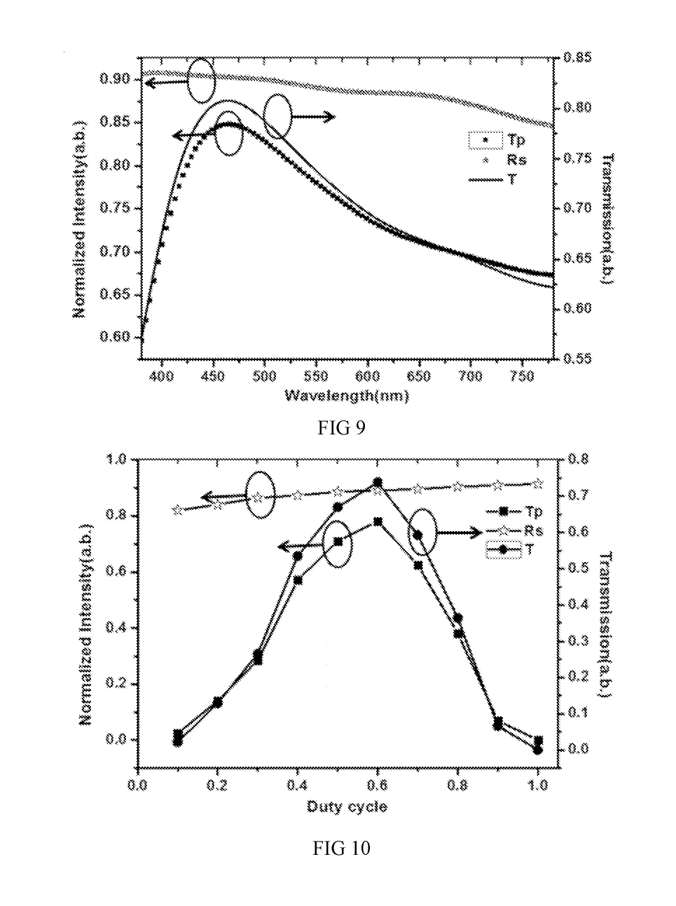

FIG. 9 is curve diagram showing the polarized optical characteristics of one enhanced dual-layers wire grid.

The parameters are P=140 nm, w=70 nm, h1=50 nm, and h2=140 nm. The dotted lines respectively relates to P-type transmittance rate and the S-type reflective rate. The solid line relates to the overall transmittance rate (T) of the enhancement film, wherein the S-type reflective rate is greater than 85%, and the P-type transmittance rate may be the minimum value, i.e., 60%, when the wavelength is 380 nm, which is the minimum wavelength. The overall transmittance rate (T) is greater than 57% within the whole wavelength band. Compared with the conventional absorption polarizer, the enhancement rate is at least 35%.

FIG. 10 is a curve diagram sowing the polarized optical characteristics of the dual-layers wire grid of FIG. 9 after the duty cycle ratio is enhanced. The duty cycle ratio is in a range from 0 to 1, wherein the wavelength is 550 nm. In view of FIG. 10, when the duty cycle ratio is 0.6, the enhancement rate reaches its maximum value, i.e., 75%

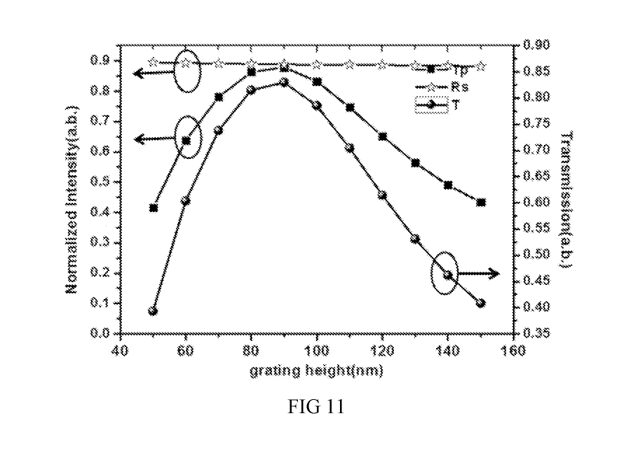

FIG. 11 is a curve diagram sowing the polarized optical characteristics of the dual-layers wire grid of FIG. 9 after the photo-resist thickness (h2) is enhanced. Taking the wavelength equaling to 550 nm as one example, when h2 equals to 90 nm, the enhancement of the enhancement film reaches its maximum value, i.e., 85%, and the enhancement ratio reaches 102%.

The fourth embodiment is characterized by high extinction ratio, which is applicable not only to the backlit enhancement film, but also applicable to the polarizer demanding high extinction ratio.

In view of the above, the photo-resist grid is manufactured by roll-to-roll nano-imprinting process. The metal films having cross sections of different shapes may be formed on the cured photo-resist grid. The manufacturing process is simple and the cost may be saved. At the same time, the substrate of the nano-imprinting process may be applicable to the wire grid enhancement film having a plurality of complicated patterns. In addition, the optical gain of the TFT-LCD may be enhanced. The P-type transmittance rate is enhanced, and the S-type reflective rate may be maintained.

Furthermore, the wire grid enhancement film for displaying backlit may be manufactured by the above manufacturing methods, and the detailed descriptions may be referred to in the above, and thus are omitted hereinafter.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A manufacturing method of enhancement films of wire grids for displaying backlit, comprising:
coating a photo-resist layer on a surface of a substrate, wherein the substrate is a flexible substrate;
adopting a nano-imprinting process to form a nano-scale photo-resist grid on a photo-resist layer, and applying a curing process, and cross sections of the photo-resist grid are a plurality of rectangles or trapeziums spaced apart from each other; and
forming a metal film on the cured photo-resist grid, and the metal film is formed on top surfaces of the rectangles and the same lateral surface by an inclined deposition method.

2. A manufacturing method of enhancement films of wire grids for displaying backlit, comprising:
coating a photo-resist layer on a surface of a substrate;
adopting a nano-imprinting process to form a nano-scale photo-resist grid on the photo-resist layer, and applying a curing process; and
forming a metal film on the cured photo-resist grid.

3. The manufacturing method as claimed in claim 2, wherein cross sections of the photo-resist grid comprise a plurality of rectangles spaced apart from each other, and the metal film is formed on top surfaces of the rectangles and the same lateral surface by an inclined deposition method.

4. The manufacturing method as claimed in claim 2, wherein cross sections of the photo-resist grid comprise a plurality of trapeziums spaced apart from each other, and the metal film is formed on top surfaces of the rectangles and the same lateral surface by an inclined deposition method.

5. The manufacturing method as claimed in claim 2, wherein cross sections of the photo-resist grid comprise a plurality of triangles spaced apart from each other, and the metal film is formed on top surfaces of the triangles and the same lateral surface by an inclined deposition method.

6. The manufacturing method as claimed in claim 2, wherein cross sections of the photo-resist grid comprise a plurality of rectangles spaced apart from each other, and the metal film is formed on top surfaces of the rectangles and gap areas between the rectangles, and the metal films on the top surfaces of the rectangles and the metal films in the gap areas are not connected.

7. The manufacturing method as claimed in claim 3, wherein a grid period is in a range from 40 to 100 nm.

8. The manufacturing method as claimed in claim 7, wherein a grid width is in a range from 10 to 50 nm.

9. The manufacturing method as claimed in claim 8, wherein a grid period is in a range from 40 to 200 nm.

10. The manufacturing method as claimed in claim 4, wherein a grid period of the photo-resist grid is in a range from 100 to 300 nm.

11. The manufacturing method as claimed in claim 10, wherein a grid width is in a range from 100 to 200 nm.

12. The manufacturing method as claimed in claim 11, wherein a grid thickness is in a range from 100 to 200 nm.

13. The manufacturing method as claimed in claim 5, wherein a grid period of the photo-resist grid is in a range from 100 to 300 nm.

14. The manufacturing method as claimed in claim 13, wherein a grid width is in a range from 100 to 200 nm.

15. The manufacturing method as claimed in claim 14, wherein a grid thickness is in a range from 100 to 200 nm.

16. The manufacturing method as claimed in claim 6, wherein a grid period of the photo-resist grid is in a range from 100 to 300 nm.

17. The manufacturing method as claimed in claim 6, wherein a grid width is in a range from 60 to 70 nm, and a grid thickness is in a range from 30 to 50 nm.

18. The manufacturing method as claimed in claim 2, wherein the substrate is a flexible substrate, and the metal film is made of Al or Ag.

19. The manufacturing method as claimed in claim 2, wherein the curing process is optical radiation or heat setting, and the metal film is formed by evaporation or sputtering.

20. A wire grid enhancement film for displaying backlit manufactured by the manufacturing method of claim 2.
